(19) United States
(12) Patent Application Publication
(10) Pub. No.: US 2001/0040274 A1
(43) Pub. Date: Nov. 15, 2001

(54) Semiconductor device

(76) Inventor: Itsuo Hidaka, Tokyo (JP)

Correspondence Address: HUTCHINS, WHEELER & DITTMAR, 101 FEDERAL STREET, BOSTON, MA, 02110, US

(21) Appl. No.: 09/525,802

(22) Filed: Mar. 15, 2000

(30) Foreign Application Priority Data
Mar. 15, 1999 (JP) 067625/1999

(51) Int. Cl. H01L 23/552

(52) U.S. Cl. 257/659; 257/664

(57) ABSTRACT

Two adjacent lines are formed in parallel to a signal line in a wiring layer where the signal line is formed. Intersection lines are formed respectively in wiring layers above and under the wiring layers where the signal line and the adjacent lines are formed, along areas which are enclosed by the adjacent lines. Entire-line-area through-holes for connecting each of the adjacent lines with a corresponding one of the intersection line are formed along the entire area of the adjacent lines, in an insulating layer between the adjacent lines and the intersection lines. The signal line is completely covered by the adjacent lines, the intersection lines and the entire-line-area through-holes. The adjacent lines, the intersection lines and the entire-line-area through-holes are maintained at a constant potential, or their electric potentials have the same phase as that of the signal line.

### BACKGROUND OF THE INVENTION

1. Field of the Invention

The present invention relates to a semiconductor device, and more particularly to the line structure adopted in the device.

2. Description of the Related Art

In general, in a semiconductor device, the occurrence of noise is due to the change in an electric potential of a signal line, typically a clock line or the like. If such noise occurs as a result of the above, crosstalk also occurs between a plurality of signal lines. Any noise may reach the signal lines from the outside of the semiconductor device. Such noise or crosstalk may lead the semiconductor device to fail to function properly. Thus, one of the most important subject matters in the field of the semiconductor device is to prevent any noise, which has occurred from one signal line, from reaching another signal line, and which comes from the outside of the semiconductor device, from reaching any of the signal lines.

Proposed in Unexamined Japanese Patent Application KOKAI Publication No. H8-274167 is a semiconductor device having the structure wherein a clock line is shielded from noise. FIG. 8 is a cross section of the structure of a conventional semiconductor device. As shown in FIG. 8, in such a semiconductor device, lines 82 and 83 having the same size in cross section as that of a clock line 81 are arranged on the both sides of the clock line 81. GND (ground) lines 85 and 86 are arranged respectively above and below the area including the clock line 81 and the lines 82 and 83. The lines 82 and 83 are connected to the GND lines 85 and 86 respectively via through-holes 84.

In the publication, the shape of the through-holes 84 is not particularly suggested. As defined in “Glossary of Semiconductor and IC terms” (edited by Takahiko Iida et al., Ohmsha, Ltd., 1980), the through-hole is “a hole connecting the top and bottom conductor layers, as formed in the middle insulating layer of the semiconductor device having the multi-layer structure”. In “Comprehensive Glossary of ULSI terms” (issued by Hirotaka Motoyama, Science Forum, Ltd., 1988), the through-hole, by definition, is a “through-hole arranged in a position where conductor layers are required to be electrically connected with each other”.

In consideration of the above-described publication and the definitions from the references, the through-hole 84 shown in the publication is meant to be a simple hole for connecting conductor layers. The semiconductor device of the publication, as shown in the perspective diagram of FIG. 9, can be considered as having the line structure wherein slits 87 are formed between the through-holes 84.

In the above-described publication, it is described that the lines 82 and 83 and the GND lines 85 and 86 are the only ones which have a function for shielding the clock line 81 from any noise (in paragraph 9 of the publication). In the publication, the through-holes 84 are described as connecting the lines 82 and 83 to the GND lines 85 and 86. However, no disclosure has been made to an aspect that the through-holes 84 themselves have a certain kind of function except to connect the lines.

In such a conventional semiconductor device having the line structure shown in FIGS. 8 and 9, a problem arises in that noises reach the signal lines 81 from any other signal lines or from the outside via the slits 87 between the through-holes 84. Another problem is that the noise occurred from the signal line 81 reaches any other signal lines via the slits 87 formed between the through-holes 84.

### SUMMARY OF THE INVENTION

It is accordingly an object of the present invention to provide a semiconductor device, wherein any externally-generated noise does not reach a signal line included in the device.

Another object of the present invention is to provide a semiconductor device, wherein crosstalk, which occurs as a result of noise generated by a signal line, occurring in any other line is preventable.

In order to achieve the above-described objects, according to the first aspect of the present invention, there is provided a semiconductor device having multiple wiring layers, the device comprising:

a signal line which is formed in a wiring layer, and to which a signal voltage is applied;

two adjacent lines which are so adjacent to the signal line as not to be connected thereto, and which are formed in a wiring layer where the signal line is formed;

two intersection lines which are respectively formed in wiring layers each being present via an insulating layer over or under the wiring layer where the signal line and the adjacent lines are formed, and which are formed along a surface area corresponding to an area which is enclosed by the two adjacent lines; and

a plurality of entire-line-area through-holes which respectively penetrate through the insulating layers formed between the adjacent lines and the two intersection lines, respectively along an entire area of each of the two adjacent lines, and which respectively and electrically connect the two adjacent lines and the two intersection lines.

In the semiconductor device according to the first aspect of the present invention, the signal line, to which a signal voltage is applied, is surrounded by the adjacent lines being adjacent thereto, the two intersection line, and the entire-line-area through-holes. In light of this, any noise which occurs as a result of a change in the signal voltage and generated from the signal line is cut off by the adjacent lines, intersection lines and the entire-line-area thought holes, thus is prevented from being transmitted out. Thus, in the semiconductor device, crosstalk, which occurs as a result that the noise from the signal line have an undesirable influence on any other signal line, can be prevented.

Any noise which is emitted from a signal line other than the signal line included in the semiconductor device according to the first aspect of the present invention, or which is emitted from an electronic circuit arranged outside the semiconductor device can be cut off by the adjacent lines, the intersection lines and the entire-line-area through-holes. In addition, the signal line is shielded from such noise. Thus, the above-described semiconductor device is prevented from any error which is due to the externally-generated noise.

In the semiconductor device according to the first aspect of the present invention, the two adjacent lines may be formed substantially in parallel to the signal line.

In the semiconductor device according to the first aspect of the present invention, electric potentials of the two adjacent lines, two intersection lines and entire-line-area through-holes may be retained at a predetermined value, or may have a same phase as a phase of an electric potential of the signal line.

In order to achieve the above-described objects, according to the second aspect of the present invention, there is provided a semiconductor device having multiple wiring layers, the device having:

a plurality of signal lines which are formed not to intersect each other in an identical wiring layer, and to which signal voltages having a same phase are applied;

two adjacent lines which are so formed adjacent onto both sides of the plurality of signal lines as not to be connected thereto, and which are formed in the wiring layer where the plurality of signal lines are formed;

two intersection lines which are formed in a wiring layer each being present via insulating layers over or under the wiring layer where the plurality of signal lines and the two adjacent lines are formed, and which are formed along a surface area corresponding to an area enclosed by the two adjacent lines; and

a plurality of entire-line-area through-holes which respectively penetrate through insulating layers formed between the adjacent lines and the two intersection lines, along entire areas of the two adjacent lines, and which respectively and electrically connect the two adjacent lines with the two intersection lines.

In the semiconductor device according to the second aspect of the present invention, electric potentials of the two adjacent lines, two intersection lines and entire-line-area through-holes may be retained at a predetermined value, or may have a same phase as a phase of an electric potential of the signal lines.

In order to achieve the above-described objects, according to the third aspect of the present invention, there is provided a semiconductor device having multiple wiring layers, the device comprising:

a plurality of signal lines which are formed in parallel to each other in an identical wiring layer, and to which signal voltage having different phases are applied;

two first adjacent lines which are so formed adjacent respectively onto outer two of the plurality of signal lines as not to be connected thereto, and which are formed in the wiring layer where the plurality of signal lines are formed;

at least one second adjacent line which is formed in the wiring layer where the plurality of signal lines are formed, between the plurality of signal lines so as not to be connected to the plurality of signal lines;

two intersection lines each of which is formed in a wiring layer being present via an insulating layer above or under the wiring layer where the signal lines and the first adjacent lines are formed, and each of which is arranged along a surface area corresponding to an area enclosed by the two first adjacent lines; and

entire-line-area through-holes which respectively penetrate through insulating layers formed between the first and second adjacent lines and the two intersection lines along entire areas of the first and second adjacent lines, and which respectively and electrically connect the first and second adjacent lines with the two intersection lines.

In the semiconductor device according to the third aspect of the present invention, it is preferred that electric potentials of the first and second adjacent lines, two intersection lines and entire-line-area through-holes are retained at a predetermined value.

In order to achieve the above-described objects, according to the fourth aspect of the present invention, there is provided a semiconductor device having multiple wiring layers, the device comprising:

a plurality of signal lines which are formed not to intersect each other in different wiring layers and to which signals having a same phase are respectively applied;

a plurality of adjacent lines each pair of which are so formed adjacent onto both sides of the plurality of signal lines as not to be connected thereto in the wiring layers where the plurality of signal lines are formed;

two intersection lines each of which is formed in a layer under a lowermost wiring layer where the plurality of signal lines are formed or in a layer above an uppermost wiring layer where the plurality of signal lines are formed, and which are formed along a surface area corresponding to an area enclosed by the plurality of adjacent lines formed on the both sides of the plurality of signal lines;

a plurality of first entire-line-area through-holes which penetrate through an insulating layer arranged between the adjacent lines and the two intersection lines, along entire areas of the adjacent lines, and which electrically connect the adjacent lines with the two intersection lines; and

a plurality o second entire-line-area through-holes which penetrate through an insulating layer arranged between the adjacent lines, along the entire areas of the adjacent lines, and which electrically connects the adjacent lines with each other.

In the semiconductor device according to the fourth aspect of the present invention, electric potentials of the adjacent lines, two intersection lines and one or more first and second entire-line-area through-holes are retained at a predetermined value, or may have a same phase as a phase of an electric potential of the signal lines.

In order to achieve the above-described objects, according to the fifth aspect of the present invention, there is provided a semiconductor device having multiple wiring layers, the device comprising:

a plurality of signal lines which are formed in different wiring layers, and to which signal voltages are respectively applied;

a plurality of first adjacent lines each pair of which are formed either in a lowermost or uppermost wiring layer, of the wiring layers where the plurality of signal lines are formed, respectively adjacent onto both sides of one of the plurality of signal lines, which is formed in an identical layer, thereby not to be connected to the one of said plurality of signal lines;

two first intersection lines, each of which is formed either in a wiring layer under the lowermost wiring layer of said signal lines, or in a wiring layer above the uppermost wiring layer of said signal lines, and each of which is formed along a surface area corresponding to an area enclosed by the pair of adjacent lines formed on the both sides of a corresponding one of the plurality of signal lines formed either in the lowermost or uppermost wiring layer of said signal lines;

a second intersection line which is formed in a wiring layer formed between the wiring layers of the signal lines, and which is formed along a surface area corresponding to at least one area enclosed by the pair of adjacent lines;

a plurality of first entire-line-area through-holes which penetrate through insulating layers formed between the adjacent lines and the first intersection lines, along entire areas of the adjacent lines, thereby electrically connecting the adjacent lines with the two first intersection lines; and

a plurality second entire-line-area through-holes which penetrate through insulating layers respectively formed between the adjacent lines and the second intersection line, along entire areas of the adjacent lines, thereby electrically connecting the adjacent lines with the second intersection line.

In the semiconductor device according to the fifth aspect of the present invention, signal voltages which are out of phase may be applied to the plurality of signal lines.

In such a case, it is preferred that electric potentials of the first and second adjacent lines, first and second intersection lines and first and second entire-line-area through-holes have a same phase as an electric potential of the signal lines.

In the semiconductor device according to the fifth aspect of the present invention, the signal lines formed in different layers which are adjacent to each other may intersect each other.

In the semiconductor device according to the second to fifth aspects of the present invention, the signal line(s) is(are) enclosed with the adjacent lines being adjacent thereto, the intersection lines and the entire-line-area through-holes. Thus, likewise in the semiconductor device according to the first aspect of the present invention, in the semiconductor device according to the second to fifth aspects of the present invention, crosstalk, which occurs between the signal lines, or an error, which is due to the noise emitted and generated from outside the semiconductor device, can be prevented.

In order to achieve the above-described objects, according to the sixth aspect of the present invention, there is provided a semiconductor device having a structure in which a signal line, to which a signal voltage is applied, is entirely enclosed by one or more conductors or semiconductors, whose electric potentials are set at a predetermined value.

In order to achieve the above-describe objects, according to the seventh aspect of the present invention, there is provided a semiconductor device having a structure in which a signal line, to which a signal voltage is applied, is entirely enclosed by one or more conductors or semiconductors, to which a voltage whose electric potential has a same phase as a phase of the signal line is applied.

### BRIEF DESCRIPTION OF THE DRAWINGS

These objects and other objects and advantages of the present invention will become more apparent upon reading of the following detailed description and the accompanying drawings in which:

FIG. 1 is a perspective diagram showing the line structure of a semiconductor device according to an embodiment of the present invention;

FIG. 2 is a cross section exemplifying the layer structure of the semiconductor device according to the embodiment of the present invention;

FIG. 3 is a perspective diagram showing the line structure of a semiconductor device according to another embodiment of the present invention;

FIG. 4 is a perspective diagram showing the line structure of the semiconductor device according to another embodiment of the present invention;

FIG. 5 is a perspective diagram showing the line structure of the semiconductor device according to another embodiment of the present invention;

FIG. 6 is a perspective diagram showing the line structure of the semiconductor device according to another embodiment of the present invention;

FIG. 7 is a perspective diagram showing the line structure of the semiconductor device according to another embodiment of the present invention;

FIG. 8 is a cross section showing the line structure of a conventional semiconductor device; and

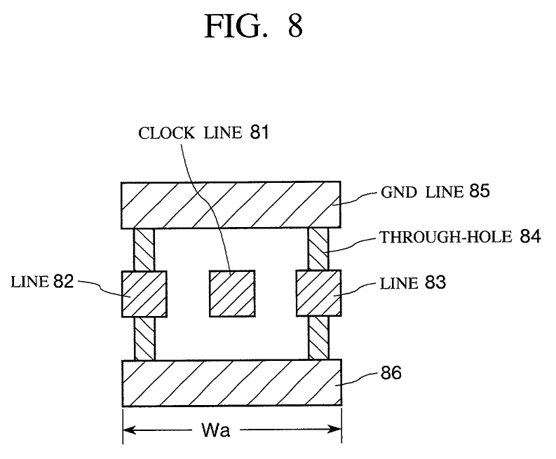

FIG. 9 is a cross section showing the line structure of a conventional semiconductor device.

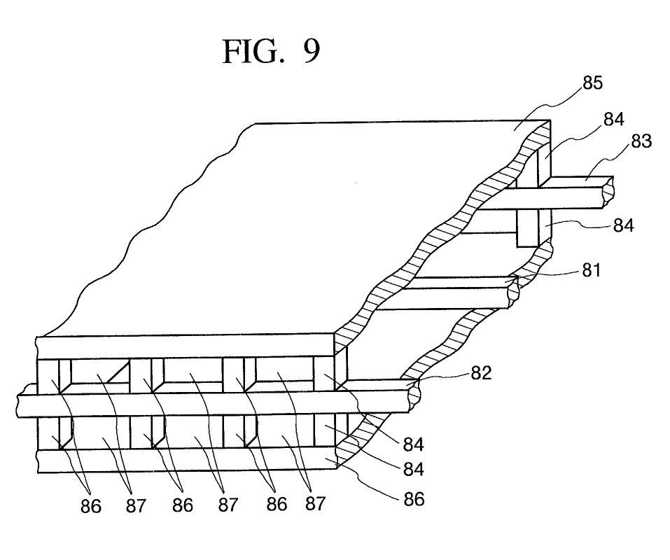

### DETAILED DESCRIPTION OF THE PREFERRED EMBODIMENTS

Preferred embodiments of the present invention will now be explained with reference to the accompanying drawings.

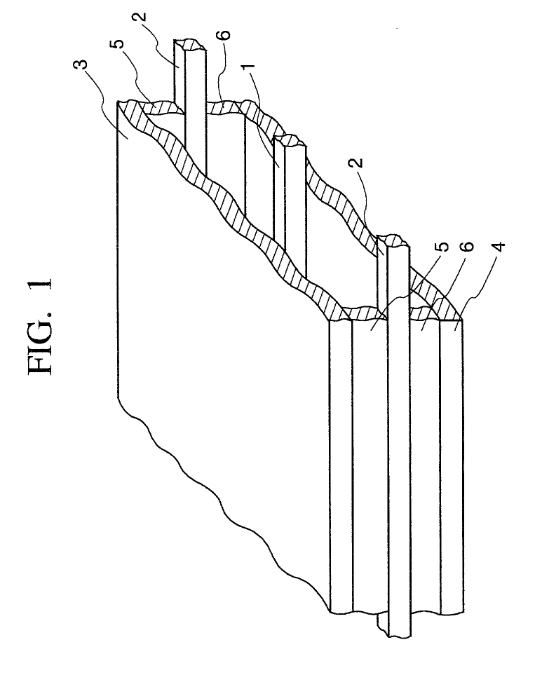

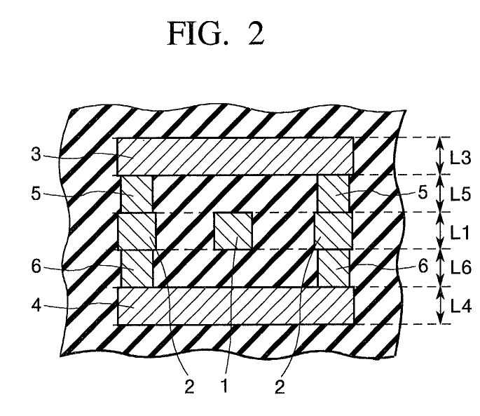

FIG. 1 is a perspective diagram showing the line structure of a semiconductor device according to an embodiment of the present invention. FIG. 2 is a cross section exemplifying the layer structure of the semiconductor device according to this embodiment.

The semiconductor device has the multi-layer structure in which wiring layers each formed from a conductor or a semiconductor and insulating layers each formed from an insulator are hierarchically arranged. In this type of semiconductor device, as shown in FIG. 1, two adjacent lines 2 are formed in parallel to and on both sides of a signal line 1, in an identical wiring layer L1 formed from the signal line 1 as a transmission path which conveys a clock signal or any other signals. Intersection lines 3 and 4 are formed along an area where the signal line 1 and the adjacent lines 2 are formed, respectively in wiring layers L3 and L4 each of which is present above or under the signal line 1 and the adjacent lines 2 via insulating layers L5 and L6.

Entire-line-area through-holes 5 and 6, for connecting the adjacent lines 2 with the intersection lines 3 and 4, are formed between the adjacent lines 2 and the intersection lines 3 and 4, in the insulating layers L5 and L6. Each of the entire-line-area through-holes 5 and 6 is made of a conductor or a semiconductor. The entire-line-area through-holes 5 and 6 are arranged entirely along the adjacent lines 2 and electrically connect the adjacent lines 2 with the intersection lines 3 and 4. The adjacent lines 2, the intersection lines 3 and 4 and the entire-line-area through-holes 5 and 6 coaxially cover the signal line 1.

One end of the signal line 1 is connected to a circuit, such as a clock pulse generating circuit or the like, which generates a signal voltage thereto. The electric potential of the signal line 1 varies in response to the generation of the signal voltage. The adjacent lines 2, the intersection lines 3 and 4 and the entire-line-area through-holes 5 and 6 are so connected with each other as to be at the same electrical potential with each other. For example, the potential is maintained at the level of the power supply voltage or the ground level (0 V).

The adjacent lines 2, the intersection lines 3 and 4 and the entire-line-area through-holes 5 and 6 all of which coaxially cover the signal line 1 may intersect any other line formed in a layer besides the layers L1 to L6.

The semiconductor device according to this embodiment will now be explained in terms of such functions, that are due to its line structure shown in FIG. 1, as (1) a function for handling noise occurring from the signal line 1 and (2) a function for handling noise occurring from any other signal line or an external line.

(1) A Function for Handling Noise Occurring from the Signal Line 1

When a signal voltage which a signal voltage generating circuit generates varies, the electric potential of the signal line 1 varies. This results in generating noise therefrom. The noise occurring form the signal line 1 is to be emitted onto the periphery of the signal line 1. However, the periphery of the signal line 1 is shielded from such noise, since it is totally covered by the adjacent lines 2, the intersection lines 3 and 4 and the entire-line-area through-holes 5 and 6. Hence, the noise occurring from the signal line 1 does not emit outside the adjacent lines 2, the intersection lines 3 and 4 and the entire-line-area through-holes 5 and 6, thereby preventing the noise from reaching any other signal line.

(2) A Function for Handling Nose Occurring from any Other Signal Line Besides the Signal Line 1 or an External Line

Likewise the signal line 1, the electric potential of any other signal lines included in the semiconductor device varies, resulting in generating noise therefrom. The noise arising from any other signal line is emitted toward the signal line 1. The noise generated from an electronic circuit which is excluded from the semiconductor device is also emitted toward the signal line 1.

Such noise emitted toward the signal line 1 is completely intercepted by the adjacent lines 2, the intersection lines 3 and 4 and the entire-line-area through-holes 5 and 6 all of which cover the periphery of the signal line 1, thus being prevented from reaching the signal line 1. Hence, the noise occurring from any signal line besides the signal line 1 in the semiconductor device, or the noise occurring from the electronic circuit which is excluded from the semiconductor device does not reach the signal line 1, eliminating the effect on the electric potential.

As explained above, in the semiconductor device according to this embodiment, the signal line 1 is completely covered by the adjacent lines 2, the intersection lines 3 and 4 and the entire-line-area through-holes 5 and 6. Thus, the signal line 1 is prevented from receiving any noise via any other signal line or via an external circuit. The noise occurring from the signal line 1 is not transmitted outside the adjacent lines 2, the intersection lines 3 and 4 and the entire-line-area through-holes 5 and 6, resulting in preventing the occurrence of crosstalk between the signal line 1 and any other signal line.

In the above-described embodiment, the adjacent lines 2, the intersection lines 3 and 4 and the entire-line-area through-holes 5 and 6 are maintained at a constant potential. However, in a case of employing the above-described line structure in a semiconductor device having the above-described signal lines in its entirety, the electric potential of adjacent lines 2, intersection lines 3 and 4 and the entire-line-area through-holes 5 and 6 all enclosing the signal line 1 may be at an electric potential having the same phase as that of the signal line 1.

In the above-described embodiment, the adjacent lines 2 are formed in parallel to the signal line 1 and adjacent onto both sides thereof. However, the adjacent lines 2 need not be formed in parallel to the signal line 1, as long as they do not intersect with the signal line 1 and completely covers the signal line 1 together with the intersection lines 3 and 4 and the entire-line-area through-holes 5 and 6.

In the above-described embodiment, the explanation has been made to the semiconductor device having the line structure, in which the single signal line 1 is completely covered by the adjacent lines 2, the intersection lines 3 and 4 and the entire-line-area through-holes 5 and 6. However, a plurality of signal lines 1 may be formed in parallel with each other in the same layer. The line structure which will be explained later may be employed in the semiconductor device, depending on whether signals to be supplied to the plurality of signal lines formed in the same layer have the same phase.

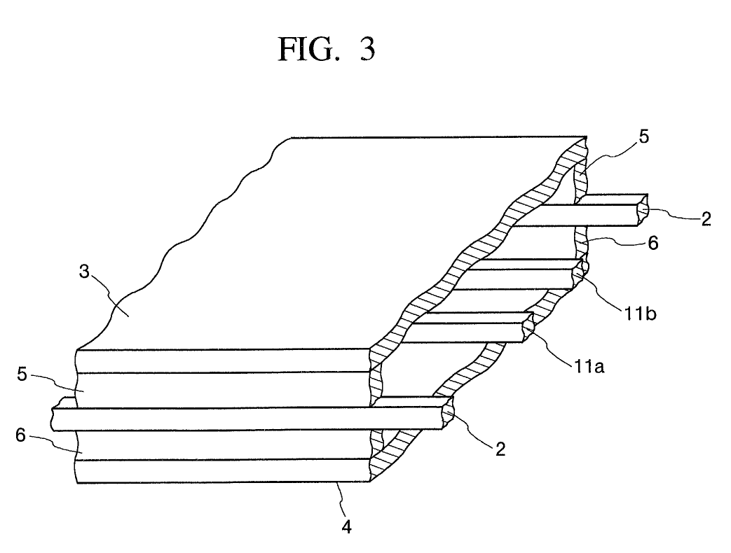

FIG. 3 is a diagram illustrating the line structure of the semiconductor device having in an identical layer a plurality of signal lines, to which signals having the same phase are supplied. In the semiconductor device illustrated in FIG. 3, two signal lines 11a and 11b formed in parallel with each other are covered by adjacent lines 2, an intersection lines 3 and 4 and entire-line-area through-holes 5 and 6. Hence, noise occurring from the two signal lines 11a and 11b is not transmitted outside such lines, at the same time, the signal lines 11a and 11b are shielded from any noise which is externally transmitted. In such a case, the adjacent lines 2, the intersection lines 3 and 4 and the entire-line-area through-holes may be at a constant potential, for example, at the level of the power supply voltage or the ground level, or their electric potentials may have the same phase as the electric potential of signal lines 31a and 32b.

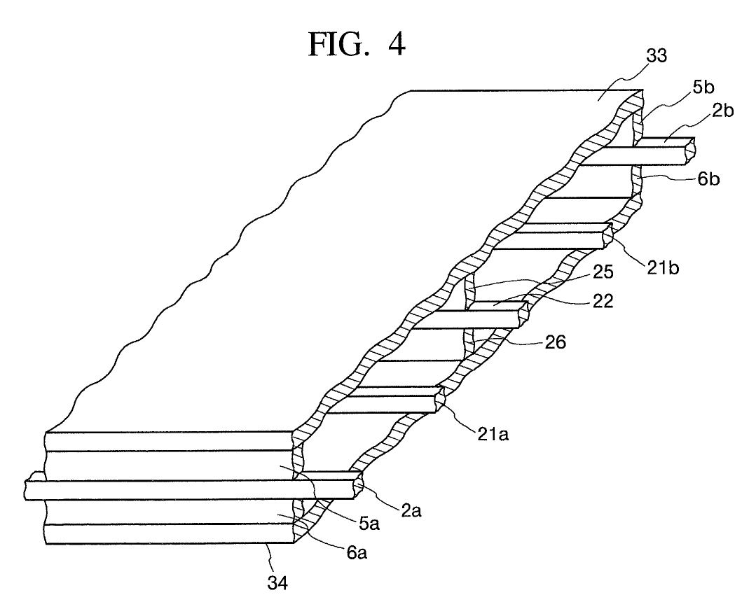

FIG. 4 is a diagram illustrating the line structure of the semiconductor device having in an identical wiring layer a plurality of signal lines, to which signal being out of phase with each other are supplied. In the semiconductor device illustrated in FIG. 4, two signal lines 21a and 21b are formed in parallel with each other in an identical layer.

In this case, an adjacent line 22 which is common to both of the signal lines 21a and 21b is formed therebetween, and adjacent lines 2a and 2b are formed respectively outside the signal lines 21a and 21b. Intersection lines 33 and 34 are formed along the entire area where the signal lines 21a and 21b, the adjacent lines 22, 2a and 2b are arranged, respectively in wiring layers each of which is present above or under such signal lines and the adjacent lines. Entire-line-area through-holes 25, 26, 5a, 6a, 5b and 6b are formed along the entire area, where the adjacent lines 22, 2a and 2b are arranged, respectively between the adjacent lines 22, 2a, 2b and the intersection lines 33 and 34. Hence, the adjacent lines 22, 2a and 2b are electrically connected to the intersection lines 33 and 34.

The signal line 21a is surrounded by the adjacent lines 2a and 2b, the intersection lines 33 and 34 and the entire-line-area through-holes 25, 26, 5a and 6b. The signal line 21b is surrounded by the adjacent lines 22 and 2b, the intersection lines 33 and 34 and the entire-line-area through-holes 25, 26, 5a and 5. In such a line structure, noise occurring from the signal lines 21a and 21b is not externally transmitted, and at the same time, the signal lines 2a and 2b are shielded from any noise generated outside the lines. In this semiconductor device, the potential of the adjacent lines 2a and 2b, the intersection lines 33 and 34 and the entire-line-area through-holes 5a, 5b, 6a, 25 and 26 can be maintained at a constant potential, for example, at the level of the power supply voltage or the ground level.

In the above-described embodiment, any signal line formed in a different wiring layer from the wiring layer where the signal line 1 is formed has not particularly been mentioned. In the semiconductor device having a plurality of signal lines in a variety of wiring layers, the line structure which will be described later can be employed, depending on whether the signal lines are formed in parallel with each other or intersect each other, or the signal potentials of the signal lines have the same phase.

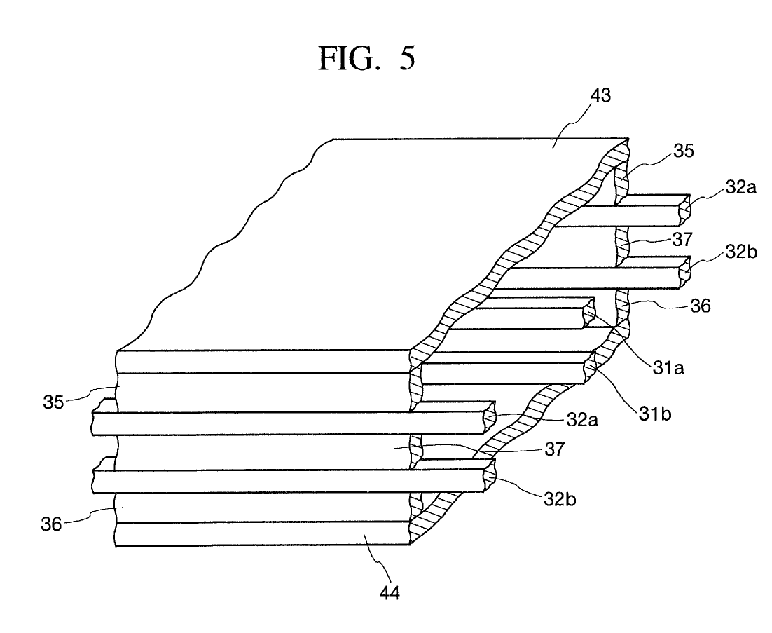

FIG. 5 is a diagram showing the structure of the semiconductor device, in which signal lines are formed in various wiring layers in parallel with each other, and the signal potentials supplied respectively to the signal lines have the same phase. In the semiconductor device illustrated in FIG. 5, two signal lines 31a and 31b are formed in adjacent wiring layers in parallel with each other.

In the adjacent wiring layers in which the two signal lines 31a and 31b are formed, two pairs of adjacent lines 32a and 32b are formed respectively on both sides of the signal lines 31a and 31b and in parallel with the signal lines 31a and 31b. Intersection lines 43 and 44 are formed in areas which are respectively enclosed by the two pairs of the adjacent lines 32a and 32b, respectively in wiring layers over and under two pairs of adjacent lines 32a and 32b. Entire-line-area through-holes 35 and 36 are so arranged along the entire areas of the adjacent lines 32a and 32b as to penetrate through the insulating layers respectively between the adjacent lines 32a and 32b and the intersection lines 43 and 44. Entire-line-area through-holes 37 are so arranged along the entire areas of the adjacent lines 32a and 32b as to penetrate through the insulating layers respectively between the adjacent lines 32a and 32b.

The signal lines 31a and 31b are surrounded by the adjacent lines 32a and 32b, the intersection lines 43 and 44 and the entire-line-area through-holes 35 to 37. In such a structure, any noise occurring from the signal lines 31a and 31b is prevented from being emitted out. In addition, any noise which has occurred from the outside does not reach the signal lines 31a and 31b. The adjacent lines 32a and 32b, the intersection lines 43 and 43 and the entire-line-area through-holes 35 to 37 may be retained at a constant potential, for example, at the level of the power source voltage or the ground level, or their electric potentials may have the same phase as the potential of the signal lines 31a and 31b.

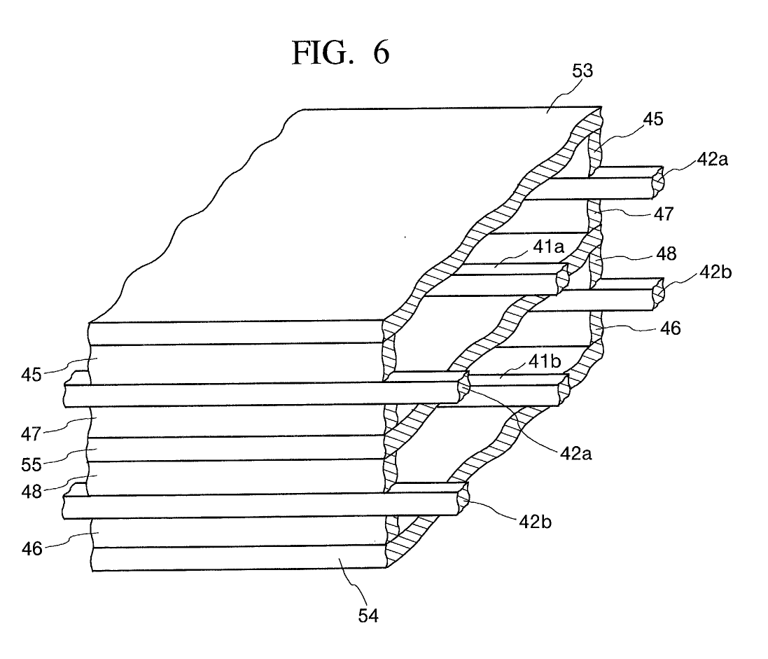

FIG. 6 is a diagram showing the structure of a semiconductor device, wherein signal lines formed in different wiring layers are in parallel with each other, and signal potentials to be supplied to the signal lines are out of phase. In the semiconductor device illustrated in FIG. 6, two signal lines 41a and 41b are formed in parallel with each other in different wiring layers.

In the wiring layers in which the two signal lines 41a and 41b are formed, two pairs of adjacent lines 42a and 42b are formed respectively on the both sides of the signal lines 41a and 41b. Intersection lines 53 and 54 are respectively formed in areas which are respectively enclosed with the two pairs of the adjacent lines 42a and 42b, in wiring layers over the adjacent line 42a and under the adjacent line 42b. In a wiring layer arranged between the wiring layer where the signal line 41a is formed and the wiring layer where the signal line 41a is formed, an intersection line 55 is formed in a manner corresponding to the area which is enclosed by the adjacent lines 42a and 42b.

Entire-line-area through-holes 45 and 46 are so arranged along the entire areas of the adjacent lines 42a and 42b as to penetrate through the insulating layers respectively between the adjacent lines 42a and 42b and the intersection lines 53 and 54. Entire-line-area through-holes 47 and 48 are so arranged along the entire areas of the adjacent lines 42a and 42b as to penetrate through the insulating layers respectively between the adjacent lines 42a and 42b and the intersection line 55.

The signal line 41a is surrounded by the adjacent line 42a, the intersection lines 53 and 55 and the entire-line-area through-holes 45 and 47. The signal line 41a is enclosed by the adjacent line 42b, the intersection lines 54 and 55 and the entire-line-area through-holes 46 and 48. In such a structure, any noise generated from the signal lines 41a and 41b is not transmitted therebeyond. In addition, the signal lines 41a and 41b are shielded from noise which is generated from the outside the lines. The adjacent lines 42a and 42b, the intersection lines 53 to 55 and the entire-line-area through-holes 45 to 48 may be retained at a constant potential, for example, at the level of the power supply voltage of the ground level.

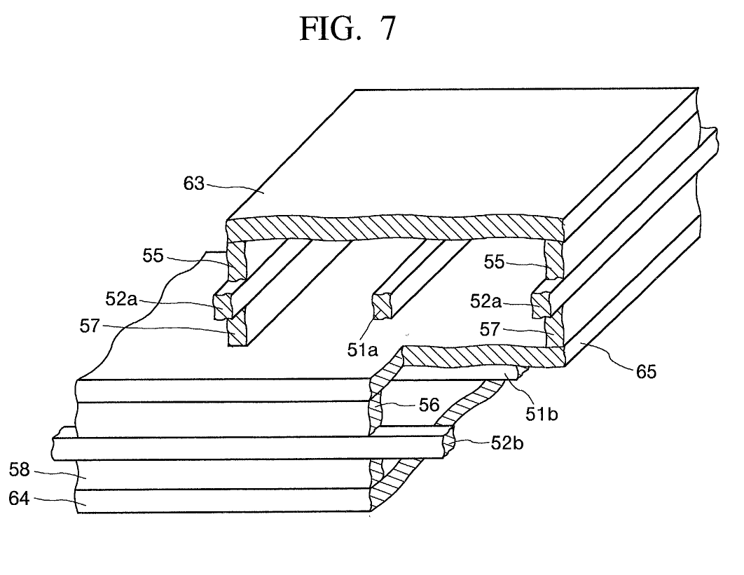

FIG. 7 is a diagram showing the structure of a semiconductor device, wherein signal lines formed in various wiring layers intersect each other. In the semiconductor device illustrated in FIG. 7, two signal lines 51a and 51b intersect each other and are formed in different wiring layers. Signal voltages to be applied to the signal lines 51a and 51b may or may not have the same phase.

In the wiring layers where the two signal lines 51a and 51b are formed, two pairs of adjacent lines 52a and 52b are formed in parallel to and respectively adjacent to the signal lines 51a and 51b. Intersection lines 63 and 64 are formed in a manner corresponding to the area which is enclosed by the adjacent lines 52a and 52b. An intersection line 65 is formed, in a manner corresponding to the area which is enclosed by the adjacent lines 52a and 52b, in the wiring layer arranged between the wiring layer where the signal line 51a, etc. is formed and the wiring layer where the signal line 51b, etc. is formed.

Entire-line-area through-holes 55 and 56 are so arranged along the entire areas of the adjacent lines 52a and 52b as to penetrate through the insulating layers respectively between the adjacent lines 52a and 52b and the intersection lines 63 and 64. Entire-line-area area through-holes 57 and 58 are so arranged along the entire areas of the adjacent lines 52a and 52b as to penetrate through the insulating layers respectively between the adjacent lines 52a and 52b and the intersection line 65.

The signal line 51a is enclosed by the adjacent lines 52a, the intersection lines 63 and 54 and the entire-line-area through-holes 55 and 57. The signal line 51b is enclosed by the adjacent line 52b, the intersection lines 64 and 65 and the entire-line-area through-holes 56 and 58. In such a structure, any noise emitted by the signal lines 51a and 51b is not transmitted out. In addition, the signal lines 51a and 51b are shielded from such noise generated outside the signal lines. In a case where the signal voltages to be applied to the signal lines 51a and 51b have the same phase, the adjacent lines 52a and 52b, the intersection lines 63 to 65 and the entire-line-area through-holes 55 to 58 may be retained at a constant potential, for example, at the level of the power supply voltage of the ground level. Otherwise, the electric potential of such lines may have the same phase as that of the electric potential of the signal lines 31a and 31b. On the contrary, in a case where the signal voltages to be applied thereto do not have the same phase, such lines may be retained at a constant potential, for example, at the level of the power supply voltage of the ground level.

Various embodiments and changes may be made thereonto without departing from the broad spirit and scope of the invention. The above-described embodiment is intended to illustrate the present invention, not to limit the scope of the present invention. The scope of the present invention is shown by the attached claims rather than the embodiment. Various modifications made within the meaning of an equivalent of the claims of the invention and within the claims are to be regarded to be in the scope of the present invention.

This application is based on Japanese Patent Application No. H11-067625 filed on Mar. 15, 1999, and including specification, claims, drawings and summary. The disclosure of the above Japanese Patent Application is incorporated herein by reference in its entirety.

What is claimed is:

1. A semiconductor device having multiple wiring layers, comprising:
a signal line which is formed in a wiring layer, and to which a signal voltage is applied;
two adjacent lines which are so adjacent to said signal line as not to be connected thereto, and which are formed in a wiring layer where said signal line is formed;
two intersection lines which are respectively formed in wiring layers each being present via an insulating layer above or under the wiring layer where said signal line and said adjacent lines are formed, and which are formed along a surface area corresponding to an area which is enclosed by said two adjacent lines; and
a plurality of entire-line-area through-holes which respectively penetrate through the insulating layers formed between said adjacent lines and said two intersection lines, along entire areas of said two adjacent lines, and which respectively and electrically connect said two adjacent lines and said two intersection lines.

2. The semiconductor device according to claim 1, wherein said two adjacent lines are formed substantially in parallel to said signal line.

3. The semiconductor device according to claim 1, wherein electric potentials of said two adjacent lines, two intersection lines and entire-line-area through-holes are retained at a predetermined value.

4. The semiconductor device according to claim 1, the electric potentials of said two adjacent lines, said two intersection lines and said entire-line-area through-hole have a same phase as a phase of an electric potential of said signal line.

5. A semiconductor device having multiple wiring layers, comprising:
a plurality of signal lines which are formed not to intersect each other in an identical wiring layer, and to which signal voltages having a same phase are applied;
two adjacent lines which are so formed adjacent onto both sides of said plurality of signal lines as not to be connected thereto, and which are formed in the wiring layer where said plurality of signal lines are formed;
two intersection lines which are formed in a wiring layer each being present via insulating layers above or under the wiring layer where said plurality of signal lines and said two adjacent lines are formed, and which are formed along a surface area corresponding to an area enclosed by said two adjacent lines; and
a plurality of entire-line-area through-holes which respectively penetrate through insulating layers formed between said adjacent lines and said two intersection lines, along entire areas of said two adjacent lines, and which respectively and electrically connect said two adjacent lines with said two intersection lines.

6. The semiconductor device according to claim 5, wherein electric potentials of said two adjacent lines, two intersection lines and entire-line-area through-holes are retained at a predetermined value.

7. The semiconductor device according to claim 6, wherein the electric potentials of said two adjacent lines, two intersection lines and entire-line-area through-holes have a same phase as a phase of an electric potential of said signal lines.

8. A semiconductor device having multiple wiring layers, said device comprising:
a plurality of signal lines which are formed not to intersect each other in an identical wiring layer, and to which signal voltage having different phases are applied;
two first adjacent lines which are so formed adjacent respectively onto outer two of said plurality of signal lines as not to be connected thereto, and which are formed in the wiring layer where said plurality of signal lines are formed;
at least one second adjacent line which is formed in the wiring layer where said plurality of signal lines are formed, between said plurality of signal lines so as not to be connected to said plurality of signal lines;
two intersection lines each of which is formed in a wiring layer being present via an insulating layer above or under the wiring layer where said signal lines and said first adjacent lines are formed, and each of which is arranged along a surface area corresponding to an area enclosed by said two first adjacent lines; and
entire-line-area through-holes which respectively penetrate through insulating layers formed between said first and second adjacent lines and said two intersection lines along entire areas of said first and second adjacent lines, and which respectively and electrically connect said first and second adjacent lines with said two intersection lines.

9. The semiconductor device according to claim 7, wherein electric potentials of said first and second adjacent lines, two intersection lines and entire-line-area through-holes are retained at a predetermined value.

10. A semiconductor device having multiple wiring layers, said device comprising:
a plurality of signal lines which are formed substantially in parallel to each other in different wiring layers and to which signals having a same phase are respectively applied;
a plurality of adjacent lines each pair of which are so formed adjacent onto both sides of said plurality of signal lines as not to be connected thereto in the wiring layers where said plurality of signal lines are formed;
two intersection lines each of which is formed in a layer under a lowermost wiring layer where said plurality of signal lines are formed or in a layer above an uppermost wiring layer where said plurality of signal lines are formed, and which are formed along a surface area corresponding to an area enclosed by said plurality of adjacent lines formed on the both extreme sides of said plurality of signal lines;
a plurality of first entire-line-area through-holes which penetrate through an insulating layer arranged between said adjacent lines and said two intersection lines, along entire areas of said adjacent lines, and which electrically connect said adjacent lines with said two intersection lines; and
a plurality of second entire-line-area through-holes which penetrate through an insulating layer arranged between said adjacent lines, along the entire areas of said adjacent lines, and which electrically connects said adjacent lines with each other.

11. The semiconductor device according to claim 10, wherein electric potentials of said adjacent lines, two intersection lines and one or more first and second entire-line-area through-holes are retained at a predetermined value.

12. The semiconductor device according to claim 11, wherein the electric potentials of said adjacent lines, two intersection lines and one or more first and second entire-line-area through-holes have a same phase as a phase of an electric potential of said signal lines.

13. A semiconductor device having multiple wiring layers, said device comprising:
a plurality of signal lines which are formed in different wiring layers, and to which signal voltages are respectively applied;
a plurality of adjacent lines each pair of which are formed either in a lowermost or uppermost wiring layer, of the wiring layers where said plurality of signal lines are formed, respectively adjacent onto both sides of one of said plurality of signal lines which is formed in an identical layer, thereby not to be connected to the one of said plurality of signal lines;
two first intersection lines, each of which is formed either in a wiring layer under the lowermost wiring layer of said signal lines, or in a wiring layer above the uppermost wiring layer of said signal lines, and each of which is formed along a surface area corresponding to an area enclosed by said pair of adjacent lines formed on the both sides of a corresponding one of said plurality of signal lines formed either in the lowermost or uppermost wiring layer of said signal lines;
a second intersection line which is formed in a wiring layer formed between said wiring layers of said signal lines, and which is formed along a surface area corresponding to at least one area enclosed by said pair of adjacent lines;
a plurality of first entire-line-area through-holes which penetrate through insulating layers respectively formed between said adjacent lines and said first intersection lines, along entire areas of said adjacent lines, thereby electrically connecting said adjacent lines with said two first intersection lines; and
a plurality of second entire-line-area through-holes which penetrate through insulating layers respectively formed between said adjacent lines and said second intersection lines, along entire areas of said adjacent lines, thereby electrically connecting said adjacent lines with said second intersection line.

14. The semiconductor device according to claim 13, wherein signal voltages which are out of phase are respectively applied to said plurality of signal lines.

15. The semiconductor device according to claim 14, wherein electric potentials of said first and second adjacent lines, first and second intersection lines and first and second entire-line-area through-holes have a same phase as an electric potential of said signal lines.

16. The semiconductor device according to claim 13, wherein said signal lines formed in different layers which are adjacent to each other intersect each other.

17. A semiconductor device having a structure in which a signal line, to which a signal voltage is applied, is entirely enclosed by one or more conductors or semiconductors, whose electric potentials are set at a predetermined value.

18. A semiconductor device having a structure in which a signal line, to which a signal voltage is applied, is entirely enclosed by one or more conductors or semiconductors, to which a voltage whose electric potential has a same phase as a phase of said signal line is applied.
